(19) United States
(12) Patent Application Publication
(10) Pub. No.: US 2015/0144390 A1
(43) Pub. Date: May 28, 2015

(54) WIRING BOARD AND METHOD FOR MOUNTING SEMICONDUCTOR ELEMENT ON WIRING BOARD

(71) Applicant: KYOCERA CIRCUIT SOLUTIONS, INC., Yasu-shi (JP)

(72) Inventor: Takayuki NEJIME, Ritto-shi (JP)

(73) Assignee: KYOCERA CIRCUIT SOLUTIONS, INC., Yasu-shi (JP)

(21) Appl. No.: 14/552,928

(22) Filed: Nov. 25, 2014

(30) Foreign Application Priority Data
Nov. 28, 2013 (JP) 2013-245834

(51) Int. Cl. H01L 23/00; H05K 3/34; H05K 1/11

(52) U.S. Cl. CPC H01L 24/81; H05K 1/111; H05K 3/34; H01L 2224/81193; H01L 2224/81801; H01L 2924/351; H01L 2924/381; H05K 2201/10204; H05K 2201/09418
USPC 174/261; 228/179.1

(57) ABSTRACT

A wiring board of the present invention includes an insulating board having a mounting portion on an upper surface to mount a semiconductor element, and semiconductor element connection pads formed on the mounting portion, on which at least three first dummy pads arranged on a center portion of the mounting portion, and at least three second dummy pads arranged on a peripheral portion of the mounting portion, are formed, and a dummy solder bump is formed on each of the first dummy pad and the second dummy pad.

### BACKGROUND OF THE INVENTION

1. Field of the Invention

The present invention relates to a high-density wiring board, and a method for mounting a semiconductor element on the wiring board.

2. Description of Related Art

Conventionally, when the semiconductor element such as a semiconductor integrated circuit element is mounted on the wiring board, a semiconductor element S′ and a wiring board B are prepared as shown in FIG. 3A, for example. The semiconductor element S′ is mainly formed of silicon, and on its lower surface, a plurality of electrode terminals T′ to be connected to the wiring board B are arranged in a grid-like shape, for example at an arrangement pitch P2′. Each of the electrode terminals T′ is covered with a solder bump H′. For example, according to a semiconductor device disclosed in Japanese Unexamined Patent Application No. 2009-188260, a semiconductor chip is connected to an electrode of a mounting board through a bump.

The wiring board B is mainly formed of a resin material such as an epoxy resin, and has a mounting portion 11a to mount the semiconductor element S′, on a center portion of its upper surface. On this mounting portion 11a, a plurality of semiconductor element connection pads 12 to be connected to the electrode terminals T′ of the semiconductor element S′ through the solder bump H′ are formed and arranged at an arrangement pitch P1′ which is substantially the same as the arrangement pitch P2′ of the electrode terminals T′ of the semiconductor element S′.

Then, as shown in FIG. 3B, the electrode terminals T′ of the semiconductor element S′ are set on the respectively corresponding semiconductor element connection pads 12. This setting is performed at room temperature. The wiring board B mounting the semiconductor element S′ is put in a reflow furnace, heated to a melting temperature or higher of the solder bump H′ to melt the solder bump H′, and then cooled down to room temperature. By this reflow process, the semiconductor element S′ is mounted on the wiring board B as shown in FIG. 3C.

At this time, since a thermal expansion coefficient of the wiring board B formed of the resin material such as the epoxy resin is greater than a thermal expansion coefficient of the semiconductor element S′ formed of silicon, the wiring board B is thermally expanded more than the semiconductor element S′ at the melting temperature of the solder bump H′. Therefore, while the arrangement pitch P2′ of the electrode terminals T′ is substantially the same as the arrangement pitch P1′ of the semiconductor element connection pads 12 at the room temperature before the reflow process, the arrangement pitch P1′ of the semiconductor element connection pads 12 becomes greater than the arrangement pitch P2′ of the electrode terminals T′ at the melting temperature of the solder bump H′ in the reflow process. Thus, some electrode terminals T′ are not arranged just above the semiconductor element connection pads 12, and some electrode terminal T′ are bonded to the semiconductor element connection pads 12 in a misaligned way. As a result, they are not sufficiently connected to each other, or bonded while the semiconductor element S′ is inclined, so that when the misalignment is large, they could not be bonded to each other. Especially, in a case where the semiconductor element S′ are highly densified and the arrangement pitch P2′ is small, or a size of the semiconductor element S′ is large, such problem tends to be easily generated.

Thus, in order to avoid the above problem, as shown in FIG. 4, the present inventor has come up with an idea that the arrangement pitch P1′ of the semiconductor element connection pads 22 is set smaller than the arrangement pitch P2′ of the electrode terminals T′ at room temperature before the reflow process. That is, the arrangement pitch P2′ of the electrode terminals T′ and the arrangement pitch P1′ of the semiconductor element connection pads 22 are set so as to substantially coincide with each other at the melting temperature of the solder bump H′ in the reflow process, and the temperature is decreased to room temperature after the reflow process, so that the electrode terminal T′ and the semiconductor element connection pad 22 are bonded through the solder bump H′ under the condition that the arrangement pitch P2′ and the arrangement pitch P1′ substantially coincide with each other.

However, according to the method for mounting shown in FIG. 4, the arrangement pitch P1′ of the semiconductor element connection pads 22 is smaller than the arrangement pitch P2′ of the electrode terminals T′ at room temperature, so that when the solder bump H′ formed on the electrode terminal T′ of the semiconductor element S′ is set on each corresponding semiconductor element connection pad 22, especially the solder bump H′ arranged on an outer periphery part of the semiconductor element S′ could partially protrude from the corresponding semiconductor element connection pad 22. Therefore, the reflow process is performed under the condition that some of the solder bumps H′ are misaligned and sandwiched between the adjacent semiconductor element connection pads 22. Therefore, when a wiring board C is thermally expanded in the reflow process, some of the solder bumps H′ are caught by the semiconductor element connection pads 22 and dislocated, so that the semiconductor element S′ cannot be mounted on the wiring board C with high precision in some cases.

### SUMMARY OF THE INVENTION

An object of the present invention is to provide a wiring board capable of mounting a semiconductor element with high precision and achieving the mounting with high connection reliability with the semiconductor element, and a method for mounting the semiconductor element on the wiring board even when a thermal expansion coefficient of the wiring board is higher than a thermal expansion coefficient of the semiconductor element.

A wiring board according to the present invention includes an insulating board having a rectangular mounting portion on an upper surface to mount a semiconductor element, a plurality of semiconductor element connection pads formed on the mounting portion, wherein at least three first dummy pads arranged on a center portion of the mounting portion so as to surround the center portion, and at least three second dummy pads arranged on a peripheral portion of the mounting portion so as to surround the center portion, are formed, a dummy solder bump is formed on each of the first and second dummy pads, and a height of the dummy solder bump is greater than a total of a height of an electrode terminal formed on the semiconductor element to be mounted and a height of a solder bump formed on the electrode terminal.

A method for mounting a semiconductor element according to the present invention includes the following steps (1) to (4).

(1) a step of preparing the above-described wiring board,

(2) a step of preparing the semiconductor element in such a manner that on a lower surface of a semiconductor board having a size corresponding to a mounting portion of the wiring board, a first electrode terminal positioned on a center of the lower surface is formed and second electrode terminals are formed so as to correspond to an arrangement of semiconductor element connection pads of the mounting portion, a solder bump is formed on each of the first and second electrode terminals so that a total of a height of the electrode terminal and a height of the solder bump is smaller than a height of a dummy solder bump formed on a first dummy pad of the mounting portion, and a pitch of the second electrode terminals is set to substantially coincide with a pitch of the semiconductor element connection pads of the wiring board at a melting temperature of the solder bump and the dummy solder bump of the wiring board,

(3) a step of mounting the semiconductor element on the mounting portion in such a manner that the solder bump formed on the first electrode terminal is inserted into a space surrounded by the dummy solder bumps formed on the first dummy pads of the wiring board, and a peripheral portion of the lower surface of the semiconductor element abut on the dummy solder bumps formed on the second dummy pads of the wiring board, and

(4) a step of connecting the first electrode terminal to the first dummy pads with solders of the solder bump and the dummy solder bump, and connecting the second electrode terminal to the semiconductor element connection pad with the solder of the solder bump by heating the wiring board and the semiconductor element to the melting temperature of the solder bump and the dummy solder bump.

According to the wiring board of the present invention, at least three of the first dummy pads are arranged on the center portion of the mounting portion so as to surround the center portion, at least three of the second dummy pads are arranged on each of the peripheral portion of the mounting portion, and the dummy solder bump having the specific height is formed on each of the first and second dummy pads. As for the semiconductor element to be mounted on the wiring board, the first electrode terminal is provided in the center of its lower surface, the second electrode terminals are arranged so as to correspond to the arrangement of the semiconductor element connection pads, and the solder bump is provided on each of the electrode terminals so that the total of the height of the electrode terminal and the height of the solder bump is smaller than the height of the dummy solder bump.

Thus, when the semiconductor element is mounted, the semiconductor element is set on the mounting portion so that the solder bump formed on the first electrode terminal is inserted into the space surrounded by the dummy solder bumps formed on the first dummy pads. At this time, as for the solder bump formed on the second electrode terminal of the semiconductor element, since the total of the height of the second electrode terminal and the height of the solder bump is smaller than the height of the dummy solder bump, the solder bump does not reach the wiring board, and is not sandwiched between the semiconductor element connection pads.

In addition, the solder bump formed on the first electrode terminal positioned in the center of the lower surface of the semiconductor element is inserted into the space surrounded by the dummy solder bumps formed on the first dummy pads, and fixed thereon. Therefore, even when the wiring board is thermally expanded while the temperature rises in the reflow process, the position of the semiconductor element mounted on the wiring board can be prevented from being misaligned. Furthermore, at the solder melting temperature, the solder bump formed on the first electrode terminal and the dummy solder bumps formed on the first dummy pads are melted and bonded to each other under the condition that the position of the second electrode terminal substantially coincides with that of the semiconductor element connection pad. As a result, it is possible to provide the wiring board capable of mounting the semiconductor element with high precision, and achieving the mounting with high connection reliability.

According to the mounting method of the present invention, the solder bump is formed on the second electrode terminal such that the total of the height of the second electrode terminal and the height of the solder bump is smaller than the height of the dummy solder bump, so that when the semiconductor element is set on the mounting portion, the solder bump does not reach the wiring board. Therefore, the arrangement pitch of the semiconductor element connection pads is set smaller than the arrangement pitch of the second electrode terminals at room temperature before the reflow process. That is, although the second electrode terminal does not coincide with the semiconductor element connection pad, it is not sandwiched between the semiconductor element connection pads. Therefore, according to the method for mounting of the present invention, when the wiring board is thermally expanded in the reflow process, the solder bump is not caught by the semiconductor element connection pad and the semiconductor element is not misaligned, so that the semiconductor element can be mounted on the wiring board with high precision, and the mounting can be high in connection reliability.

### BRIEF DESCRIPTION OF THE DRAWINGS

FIGS. 1A and 1B are a schematic cross-sectional view and a top view, respectively, showing one embodiment of a wiring board according to the present invention.

FIGS. 2A to 2C are schematic cross-sectional views showing one embodiment of a method for mounting a semiconductor element according to the present invention.

FIGS. 3A to 3C are schematic cross-sectional views showing a conventional method for mounting a semiconductor element.

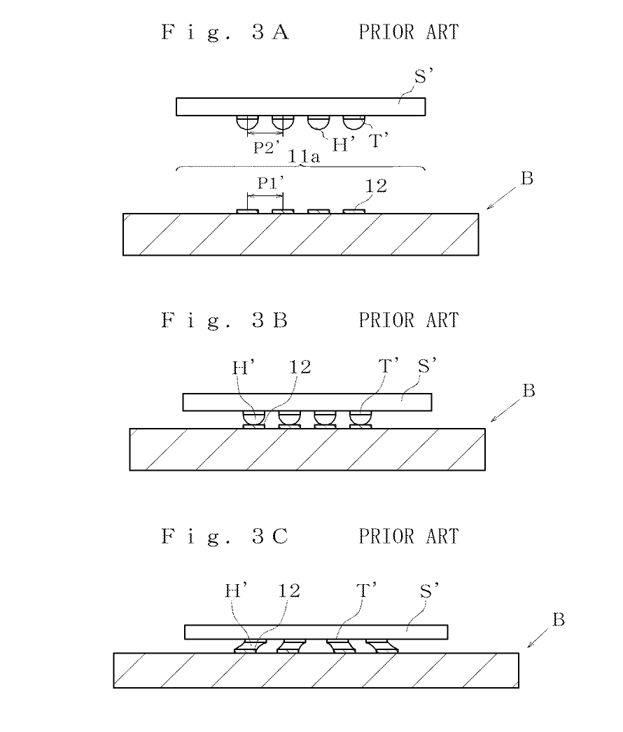

FIG. 4 is a schematic cross-sectional view showing a conventional wiring board.

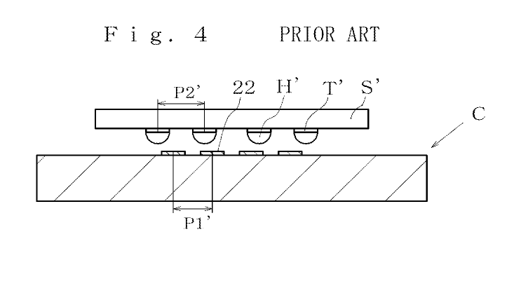

### DESCRIPTION OF THE PREFERRED EMBODIMENTS

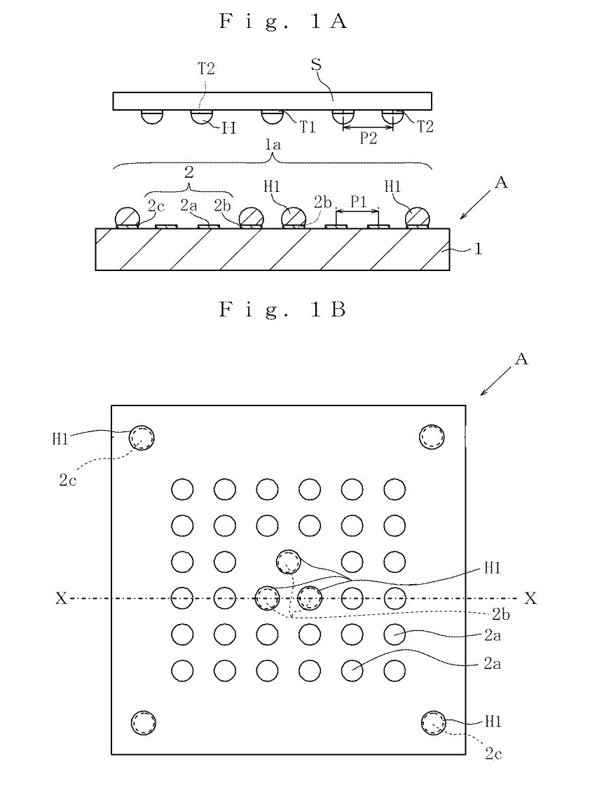

Next, one embodiment of the wiring board according to the present invention will be described with reference to FIGS. 1A and 1B. In addition, FIG. 1A is a cross-sectional view taken along a line X-X shown in FIG. 1B. As shown in FIG. 1A, a wiring board A of the present invention mainly includes an insulating board 1 and pads 2.

The insulating board 1 is formed of an electric insulating material prepared by impregnating a glass cloth with a thermosetting resin such as an epoxy resin or bismaleimide triazine resin. The insulating board 1 has a mounting portion 1a on its upper surface to mount a semiconductor element S. The insulating board 1 shown in FIG. 1A has a single-layer structure, but may have a multilayer structure having multiple laminated insulating layers each formed of the same or a different electric insulating material. The semiconductor element S has a first electrode terminal T1 on a center of a lower surface of a semiconductor board formed of silicon and has a plurality of second electrode terminals T2 arranged in a grid-like shape except for the center. The center of the lower surface of the semiconductor board having a square shape corresponds to an intersection point of two diagonal lines.

The pad 2 is made of a metal having good conductivity such as copper foil or copper plating. The pads 2 include three kinds such as a semiconductor element connection pad 2a, a first dummy pad 2b, and a second dummy pad 2c. A plurality of the semiconductor element connection pads 2a are arranged on the mounting portion 1a so as to correspond to the second electrode terminals T2 formed on the semiconductor element S. The semiconductor element connection pad 2a is connected to the second electrode terminal T2 through a solder bump H formed on the second electrode terminal T2 of the semiconductor element S. According to the wiring board A shown in FIG. 1A, an arrangement pitch P1 of the semiconductor element connection pads 2a is set smaller than an arrangement pitch P2 of the second electrode terminals T2 at room temperature, in view of the fact that a thermal expansion coefficient of the insulating board 1 formed of the resin material such as the epoxy resin is greater than a thermal expansion coefficient of the semiconductor element S formed of silicon or the like so that the arrangement pitch P1 of semiconductor element connection pads 2a substantially coincides with the arrangement pitch P2 of the second electrode terminals T2 at a solder melting temperature in a reflow process.

The three first dummy pads 2b are arranged on a center of the mounting portion 1a so as to surround the center of the mounting portion 1a, and a dummy solder bump H1 is formed on each of the first dummy pads 2b. The second dummy pad 2c is arranged on each of four corners of the mounting portion 1a, and the dummy solder bump H1 is also formed on the second dummy pad 2c. The dummy solder bump H1 has a height greater than a total of a height (thickness) of the first or second electrode terminal T1 or T2 and a height of the solder bump H.

When the semiconductor element S is mounted, the semiconductor element S is set on the mounting portion 1a in such a manner that the solder bump H formed on the first electrode terminal T1 positioned in the center of the lower surface of the semiconductor element S is inserted into a space surrounded by the dummy solder bumps H1 formed on the first dummy pads 2b, and the four corners of the lower surface of the semiconductor element S abut on the dummy solder bumps H1 formed on the second dummy pads 2c.

In this way, according to the wiring board A of the present invention, when the semiconductor element S is mounted, the semiconductor element S is set on the mounting portion 1a so that the four corners of the lower surface of the semiconductor element S abut on the dummy solder bumps H1. Therefore, the solder bump H formed on the second electrode terminal T2 of the semiconductor element S does not reach the wiring board A, and is not sandwiched between the semiconductor element connection pads 2a because the total of the height of the second electrode terminal T2 and the height of the solder bump H is smaller than the height of the dummy solder bump H1.

Furthermore, the solder bump H formed on the first electrode terminal T1 positioned in the center of the lower surface of the semiconductor element S is inserted into the space surrounded by the dummy solder bumps H1 formed on the first dummy pads 2b and fixed thereon. Therefore, even when the wiring board A is displaced due to thermal expansion while the temperature rises in the reflow process, the semiconductor element S set on the wiring board A can be prevented from being misaligned. Furthermore, at the solder melting temperature, the solder bump H formed on the first electrode terminal T1 and the dummy solder bumps H1 formed on the first dummy pads 2b are melted and bonded to each other under the condition that the position of the second electrode terminal T2 substantially coincides with that of the semiconductor element connection pad 2a. Thus, it is possible to provide the wiring board A capable of mounting the semiconductor element S with high precision and achieving the mounting with high connection reliability.

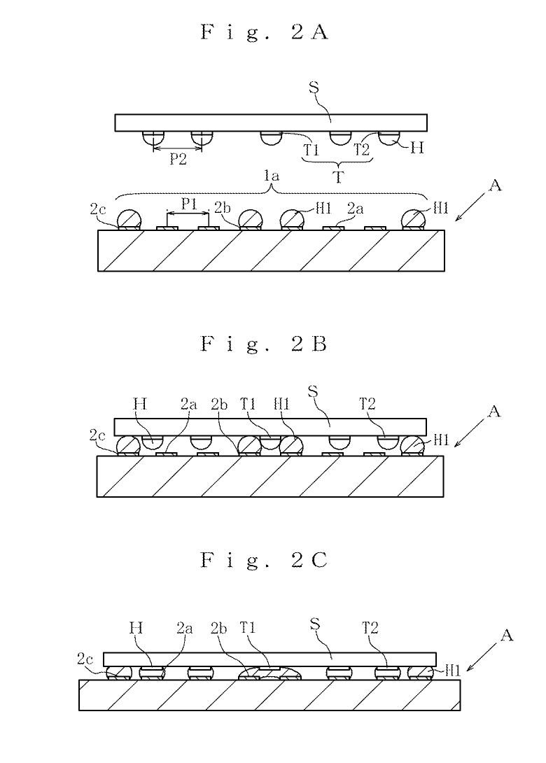

Next, one embodiment of a method for mounting of the present invention will be described with reference to FIGS. 2A to 2C. Here, the member described in FIGS. 1A and 1B is marked with the same reference characters, and its detailed description is omitted.

First, as shown in FIG. 2A, the semiconductor element S and the wiring board A are prepared. The semiconductor element S has a connection surface serving as the lower surface of the semiconductor board which is mainly formed of silicon, for example on which a plurality of the electrode terminals T are arranged. The electrode terminals T include the first electrode terminal T1 arranged in the center of the lower surface of the semiconductor element S, and the second electrode terminals T2 arranged in the grid-like shape except for the center. The second electrode terminals T2 are arranged at the arrangement pitch P2 of about 50 μm to 200 μm at room temperature. Each of the first and second electrode terminals T1 and T2 is covered with the solder bump H. The semiconductor element S has the thermal expansion coefficient of 3 ppm/° C. to 4 ppm/° C. with respect to a direction along the connection surface with the wiring board A.

As described above, the wiring board A includes the insulating board 1 and the pads 2. On the mounting portion 1a of the insulating board 1, a plurality of the semiconductor element connection pads 2a to be connected to the second electrode terminals T2 are arranged at the arrangement pitch P1 so as to correspond to the second electrode terminals T2. The arrangement pitch P1 is set to be smaller than the arrangement pitch P2 by about 0.1 μm to 1 μm at room temperature, that is, a temperature lower than the solder melting temperature, and substantially coincides with the arrangement pitch P2 of the second electrode terminals T2 at the solder melting temperature.

The three first dummy pads 2b are arranged in the center of the mounting portion 1a so as to surround the center of the mounting portion 1a, and the dummy solder bump H1 is formed on each of the first dummy pads 2b. Furthermore, one second dummy pad 2c is arranged on each of the four corners of the mounting portion 1a, and the dummy solder bump H1 is also formed on the second dummy pad 2c. The dummy solder bump H1 is formed such that its height is greater than the total of the height of the first or second electrode terminal T1 or T2 and the height of the solder bump H. Preferably, it is greater by 3 μm to 30 μm. The insulating board 1 of the wiring board A has the thermal expansion coefficient of about 10 ppm/° C. to 20 ppm/° C. with respect to the direction along a connection surface with the semiconductor element S.

Then, as shown in FIG. 2B, the semiconductor element S is set on the wiring board A so that the solder bump H of the first electrode terminal T1 is inserted into the space surrounded by the dummy solder bumps H1 on the first dummy pads 2b, and the four corners of the semiconductor element S abut on the dummy solder bumps H1 formed on the second dummy pads 2c. At this time, since the four corners of the semiconductor element S are set on the mounting portion 1a so that they abut on the dummy solder bumps H1 whose height is greater than the total of the height of the second electrode terminal T2 and the height of the solder bump H, the solder bump H does not reach the wiring board A, and is not sandwiched between the semiconductor element connection pads 2a.

Then, as shown in FIG. 2C, the wiring board A mounting the semiconductor element S is subjected to the reflow process at the solder melting temperature or higher. Since the solder bump H is not sandwiched between the semiconductor element connection pads 2a, the solder bump H is not caught by the semiconductor element connection pad 2a even when the wiring board A is thermally expanded while the temperature rises in the reflow process, so that the semiconductor element S is not misaligned.

The solder bump H formed on the first electrode terminal T1 positioned in the center of the lower surface of the semiconductor element S is inserted into the space surrounded by the dummy solder bumps H1 on the first dummy pads 2b, and fixed thereon. Therefore, even when the wiring board A is thermally expanded while the temperature rises in the reflow process, it is possible to prevent the misalignment of the position of the semiconductor element S mounted on the wiring board A. Furthermore, at the solder melting temperature, the solder bump H formed on the first electrode terminal T1 and the dummy solder bumps H1 formed on the first dummy pads 2b are melted and bonded to each other under the condition that the position of the second electrode terminal T2 substantially coincides with that of the semiconductor element connection pad 2a. As a result, the semiconductor element S can be mounted on the wiring board A with high precision, and the mounting can be achieved with high connection reliability.

Furthermore, the present invention is not limited to the above-described embodiments, and it may be variously modified within the scope described in claim. For example, according to the wiring board A shown in FIGS. 1A and 1B, the insulating board 1 has the single-layer structure, but it may have a plurality of layers each formed of the same or a different electric insulating material.

Furthermore, according to the wiring board A shown in FIGS. 1A and 1B, the center of the mounting portion 1a is surrounded by the three first dummy pads 2b, but it may be surrounded by four or more first dummy pads 2b.

Moreover, according to the wiring board A shown in FIGS. 1A and 1B, the mounting portion 1a has the square shape. However, the mounting portion is not limited to the mounting portion having the square shape, for example, the mounting portion may have a polygonal shape other than the square shape or a circular shape. According to the wiring board A shown in FIGS. 1A and 1B, since the semiconductor element S is fixed on the wiring board A more stable, one second dummy pad 2c is formed on each of the four corners of the mounting portion 1a. However, at least three second dummy pad may be formed on a peripheral portion of the mounting portion so as to surround the center portion of the mounting portion. The solder bump formed on the first electrode terminal of the semiconductor element is inserted into the space surrounded by the dummy solder bumps formed on the first dummy pads, and fixed thereon. Therefore, even when at least three second dummy pad are formed on a peripheral portion of the mounting portion so as to surround the center portion of the mounting portion, the semiconductor element is fixed on the wiring board A. In order to fix the semiconductor element more stable, when the mounting portion has the circular shape, three second dummy pads may be formed on the peripheral portion of the mounting portion every 120 degrees or four second dummy pads may be formed on the peripheral portion of the mounting portion every 90 degrees.

What is claimed is:

1. A wiring board comprising:
an insulating board having a mounting portion on an upper surface to mount a semiconductor element;
a plurality of semiconductor element connection pads formed on the mounting portion, wherein
at least three first dummy pads arranged on a center portion of the mounting portion so as to surround the center portion, and at least three second dummy pads arranged on a peripheral portion of the mounting portion so as to surround the center portion, are formed,
a dummy solder bump is formed on each of the first and second dummy pads, and
a height of the dummy solder bump is greater than a total of a height of an electrode terminal formed on the semiconductor element to be mounted and a height of a solder bump formed on the electrode terminal.

2. The wiring board according to claim 1, wherein
the insulating board has a thermal expansion coefficient of 10 ppm/° C. to 20 ppm/° C. with respect to a direction along a connection surface with the semiconductor element.

3. The wiring board according to claim 1, wherein
the semiconductor element to be mounted has a thermal expansion coefficient of 3 ppm/° C. to 4 ppm/° C. with respect to a direction along a connection surface with the wiring board.

4. The wiring board according to claim 1, wherein
the semiconductor element connection pads are formed at an arrangement pitch smaller by 0.1 μm to 1 μm than an arrangement pitch of the electrode terminals provided on the semiconductor element corresponding to the semiconductor element connection pads before being heated to a solder melting temperature.

5. A method for mounting a semiconductor element comprising steps of:
preparing the wiring board according to claim 1;
preparing the semiconductor element in such a manner that on a lower surface of a semiconductor board having a size corresponding to a mounting portion of the wiring board, a first electrode terminal positioned on a center of the lower surface is formed and second electrode terminals are formed so as to correspond to an arrangement of semiconductor element connection pads of the mounting portion, a solder bump is formed on each of the first and second electrode terminals so that a total of a height of the electrode terminal and a height of the solder bump is smaller than a height of a dummy solder bump formed on a first dummy pad of the mounting portion, and a pitch of the second electrode terminals is set to substantially coincide with a pitch of the semiconductor element connection pads of the wiring board at a melting temperature of the solder bump and the dummy solder bump of the wiring board;
mounting the semiconductor element on the mounting portion in such a manner that the solder bump formed on the first electrode terminal is inserted into a space surrounded by the dummy solder bumps formed on the first dummy pads of the wiring board, and a peripheral portion of a lower surface of the semiconductor element abut on the dummy solder bumps formed on the second dummy pads of the wiring board; and
connecting the first electrode terminal to the first dummy pads with solders of the solder bump and the dummy solder bump, and connecting the second electrode terminal to the semiconductor element connection pad with the solder of the solder bump by heating the wiring board and the semiconductor element to the melting temperature of the solder bump and the dummy solder bump.

6. The mounting method according to claim 5, wherein
an insulating board of the wiring board has a thermal expansion coefficient of 10 ppm/° C. to 20 ppm/° C. with respect to a direction along a connection surface with the semiconductor element.

7. The mounting method according to claim 5, wherein
the semiconductor element to be mounted has a thermal expansion coefficient of 3 ppm/° C. to 4 ppm/° C. with respect to a direction along a connection surface with the wiring board.

8. The mounting method according to claim 5, wherein
the semiconductor element connection pads are formed at an arrangement pitch smaller by 0.1 μm to 1 μm than an arrangement pitch of the second electrode terminals before being heated to a solder melting temperature.
